(19) United States
(12) Patent Application Publication
(10) Pub. No.: US 2016/0079410 A1
(43) Pub. Date: Mar. 17, 2016

(54) SEMICONDUCTOR DEVICE

(71) Applicant: KABUSHIKI KAISHA TOSHIBA, Tokyo (JP)

(72) Inventors: Takaaki YASUMOTO, Kawasaki Kanagawa (JP); Naoko YANASE, Inagi Tokyo (JP); Kazuhide ABE, Kawasaki Kanagawa (JP); Takeshi UCHIHARA, Kawaguchi Saitama (JP); Yasunobu SAITO, Nomi Ishikawa (JP); Hidetoshi FUJIMOTO, Kawasaki Kanagawa (JP); Masaru FURUKAWA, Himeji Hyogo (JP); Yasunari YAGI, Ibo Hyogo (JP); Miki YUMOTO, Kawasaki Kanagawa (JP); Atsuko IIDA, Yokohama Kanagawa (JP); Yukako MURAKAMI, Chigasaki Kanagawa (JP)

(21) Appl. No.: 14/637,115

(22) Filed: Mar. 3, 2015

(30) Foreign Application Priority Data
Sep. 11, 2014 (JP) 2014-185571

(51) Int. Cl. H01L 29/778; H01L 29/06; H01L 29/423; H01L 29/205; H01L 29/417; H01L 29/20; H01L 29/04

(52) U.S. Cl. CPC H01L 29/7788; H01L 29/2003; H01L 29/0692; H01L 29/04; H01L 29/205; H01L 29/7787; H01L 29/41741; H01L 29/4236

(57) ABSTRACT

A semiconductor device includes a first electrode, a second electrode, a third electrode, and a nitride semiconductor layer. The first electrode has a first surface. The second electrode has a second surface. The second surface is provided with a plurality of convex portions and concave portions. The second electrode is spaced from the first electrode in a first direction. The third electrode is spaced from the first electrode in a second direction intersecting the first direction. The nitride semiconductor layer is provided between the first surface and the second surface, and between the third electrode and the second surface.

### CROSS-REFERENCE TO RELATED APPLICATION

This application is based upon and claims the benefit of priority from Japanese Patent Application No. 2014-185571, filed Sep. 11, 2014, the entire contents of which are incorporated herein by reference.

### FIELD

Embodiments described herein relate generally to a semiconductor device.

### BACKGROUND

A semiconductor device which is formed using a nitride semiconductor such as a GaN has high insulation breakdown strength and may reduce power losses in the device. These semiconductor devices are used as a semiconductor device for power electronics and high-frequency power semiconductor devices. In the semiconductor device formed using a nitride semiconductor, improvement in the reliability thereof is desired.

### DESCRIPTION OF THE DRAWINGS

FIGS. 1A and 1B are schematic diagrams which illustrate a semiconductor device according to a first embodiment.

FIG. 2 is a schematic cross-sectional view taken along line B1-B2 of FIG. 1A.

FIG. 3 is a schematic cross-sectional view which illustrates another semiconductor device according to the first embodiment.

FIG. 4 is a schematic cross-sectional view which illustrates still another semiconductor device according to the first embodiment.

FIG. 5 is a schematic diagram which illustrates a crystal structure of a GaN-based semiconductor.

FIG. 6 is a diagram which illustrates characteristics of the GaN-based semiconductor.

FIG. 7 is a diagram which illustrates characteristics of different semiconductor materials.

FIGS. 8A and 8B are schematic cross-sectional views which illustrate a semiconductor device according to a second embodiment.

FIGS. 9A and 9B are schematic diagrams which illustrate a semiconductor device according to a third embodiment.

FIG. 10 is a schematic perspective view which illustrates a part of FIG. 9A.

FIG. 11 is a schematic cross-sectional view taken along line D1-D2 of FIG. 9A.

FIG. 12 is a schematic cross-sectional view which illustrates a semiconductor device according to a fourth embodiment.

### DETAILED DESCRIPTION

Exemplary embodiments provide a semiconductor device which may have improved reliability. In an aspect, the reliability of the semiconductor device is improved by introducing reflection surfaces for acoustic waves generated therein, to reduce the likelihood that the waves will reflect back at the same axis and amplify in amplitude. This reduces electron trapping in energy minima of the waves, which can lead to localize energy spikes leading to device damage and failure.

In general, according to one embodiment, a semiconductor device includes: a first electrode, a second electrode, a third electrode, and a nitride semiconductor layer. The first electrode has a first surface. The second electrode has a second surface. The second surface is spaced from the first surface in a first direction and has at least a portion thereof non-parallel to the first surface. The third electrode is spaced from the first electrode in a second direction intersecting the first direction. The nitride semiconductor layer is provided between the first surface and the second surface, and between the third electrode and the second surface. The non-parallel surfaces, such as the convex or concave surfaces, reduce incidence of reflected energy waves travelling in the nitride semiconductor layer being reflected back upon themselves, thereby reducing the likelihood of in phase reflected amplification of the waves leading to localized electron trapping and ultimately device failure.

Hereinafter, each exemplary embodiment will be described with reference to the drawings.

The drawings are schematic or conceptual, such that a relationship between a thickness and a width of each portion, and a size ratio between portions are not necessarily the same as those in an actual device. Moreover, even when representing the same part of a device, dimensions and ratios may be represented differently from each other in different drawings.

In later drawing figures, the same reference numerals or symbols are given to the same elements in the disclosure as those described in an earlier drawing figure and a detailed description thereof is omitted when discussing a later drawing figure as appropriate.

### First Embodiment

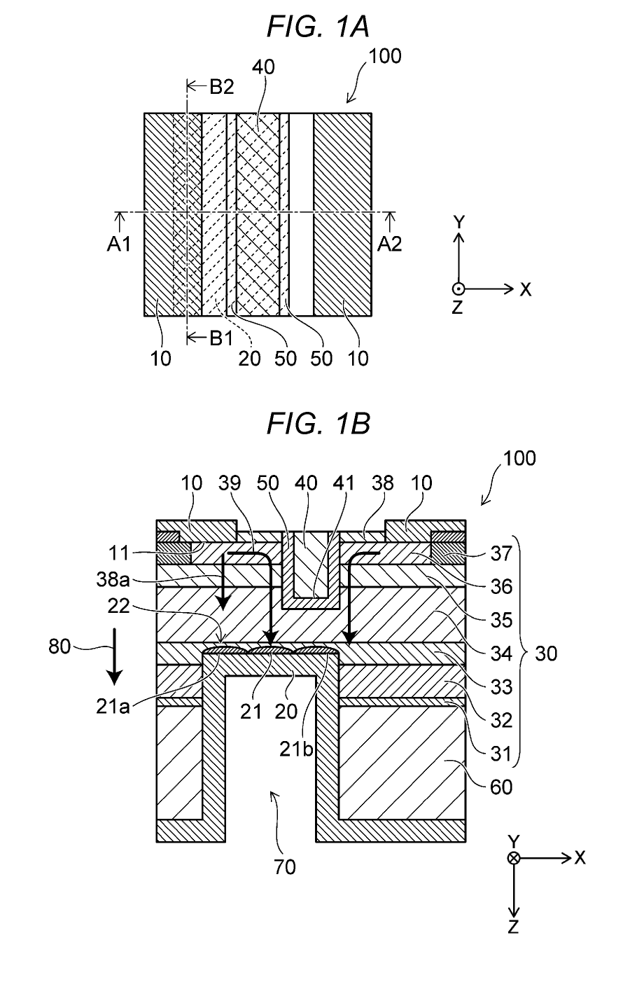

FIGS. 1A and 1B are schematic diagrams which illustrate a semiconductor device according to a first embodiment.

FIG. 1A is a schematic plan view which illustrates the semiconductor device according to the first embodiment.

FIG. 1B is a schematic cross-sectional view taken along line A1-A2 of FIG. 1A.

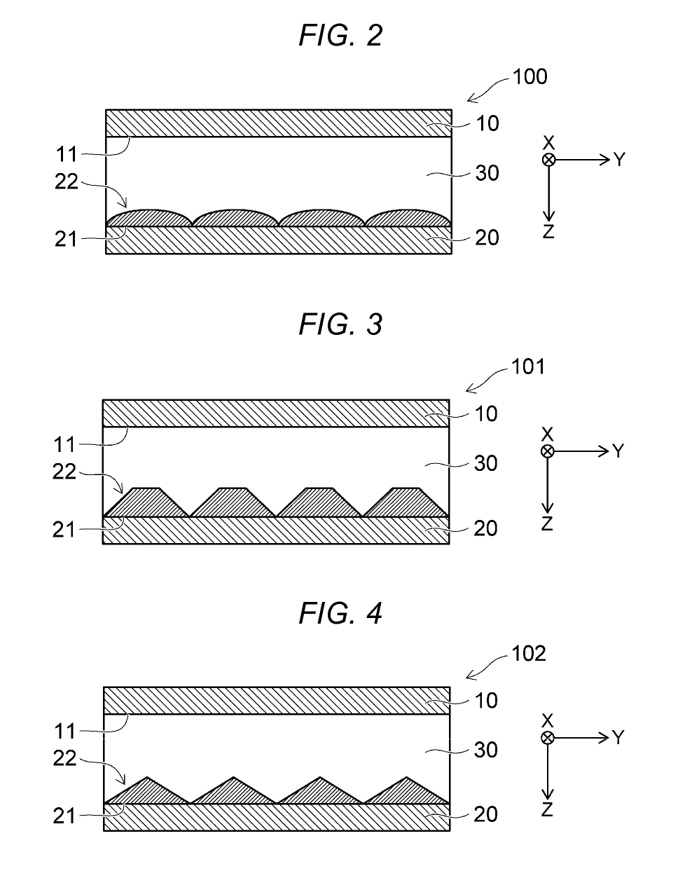

FIG. 2 is a schematic cross-sectional view taken along line B1-B2 of FIG. 1A.

As illustrated in FIGS. 1A and 1B, a semiconductor device 100 of an embodiment is a vertical transistor which uses a nitride semiconductor. The semiconductor device 100 includes a first electrode 10, a second electrode 20, a nitride semiconductor layer 30, a third electrode 40, and a substrate 60.

For example, silicon (Si) is used for the substrate 60. In addition to silicon (Si), GaN, gallium oxide (Ga₂O₃), silicon carbide (SiC), a sapphire, or the like may be used for the substrate 60.

The nitride semiconductor layer 30 is provided on the substrate 60. As a material of the nitride semiconductor layer 30, for example, GaN is used. As a material of the nitride semiconductor layer 30, AIN, InN, and the like may be used. As the nitride semiconductor layer 30, a plurality of semiconductor layers are stacked one over the other from the surface of the semiconductor substrate 60. Each semiconductor layer is formed by, for example, an epitaxial growth method.

The nitride semiconductor layer 30 includes, for example, an AIN layer 31 formed on the upper surface of the substrate 10, a buffer epitaxial (buffer) layer 32 formed over the AIN layer 31, an n⁺GaN epitaxial (n⁺GaN) layer 33 formed over the buffer epitaxial (buffer) layer 32, an n-type GaN epitaxial (nGaN) layer 34 formed over the n⁺GaN epitaxial (n⁺GaN) layer 33, a p-type GaN epitaxial (pGaN) layer 35 formed over the n-type GaN epitaxial (nGaN) layer 34, an n-type ion implanted (n implantation) layer 36 formed over portions of the p-type GaN epitaxial (pGaN) layer 35, and a p⁺GaN epitaxial (p⁺GaN) layer 37 formed over portions of the p-type GaN epitaxial (pGaN) layer 35.

The AIN layer 31 is provided on the substrate 60 and functions as a buffer layer between the underlying substrate crystal lattice and the overlying nitride layer crystal structure to transition the mismatch between the two crystal structures. Another buffer layer 32 is provided on the AIN layer 31. As the buffer layer 32, for example, GaN is used. As the buffer layer 32, a multi-layered structure of GaN and aluminum gallium nitride (AlGaN) may be used.

The n⁺GaN layer 33 is provided on the buffer layer 32. The nGaN layer 34 is provided on the n⁺GaN layer 33. The pGaN layer 35 is provided on the nGaN layer 34. The n implanted layer 36 is provided on the pGaN layer 35. The P⁺GaN layer 37 is aligned with the n implantation layer 36, and is provided on the pGaN layer 35. Each layer of the nitride semiconductor layer 30 is formed by the epitaxial growth method, respectively, for example, using a metal organic vapor phase epitaxy (MOVPE) method, respectively. The n implantation layer 36 is formed by performing ion implantation of n type dopants into layer 36 after epitaxial growth thereof.

As an n-type dopant element, for example, phosphorus (p), arsenic (As), or the like is used. As a p-type dopant element, for example, boron (B) or the like is used. Notations such as n⁺, n, n⁻ and p⁺, p, p⁻ represents a relative level of a dopant concentration of each conductivity type in a layer. That is, a layer denoted as n⁺ has a higher concentration of n type dopant than does a layer denoted as an “n” layer, and a layer denoted “n” has a higher concentration of n type dopant than does a layer denoted as “n⁻.” In addition, the p-type impurity concentration is relatively higher in p⁺ than in p, and the p-type impurity concentration is relatively lower in p⁻ than in p. In the semiconductor device 100, a p-type and an n-type conductivity may be replaced, i.e., switched with, each other.

A trench 70 is formed on a rear surface side of the substrate 60. The trench 70 passes through the substrate 60, the AIN layer 31, and the buffer layer 32, and reaches the n⁺GaN layer 33. The trench 70 is formed by etching, for example, the substrate 60, the AIN layer 31, and the buffer layer 32, thereby exposing the n⁺GaN layer 33.

The first electrode 10 is, for example, a source electrode. The first electrode 10 is provided on the nitride semiconductor layer 30. The first electrode 10 is in contact with, for example, the n implantation layer 36 and the p⁺GaN layer 37 of the nitride semiconductor layer 30. It is desirable that the first electrode 10 be in ohmic contact with the nitride semiconductor layer 30. As a material of the first electrode 10, for example, at least one of aluminum (Al), nickel (Ni), copper (Cu) and titanium (Ti) metal is used.

The second electrode 20 is provided spaced from the first electrode 10 in a first direction. The first direction is, for example, the Z-axis direction in FIG. 1B. The Z-axis direction is perpendicular to a front surface (or rear surface) of the substrate 60. The one direction perpendicular to the Z-axis direction is set to be an X-axis direction. A direction perpendicular to the Z-axis direction and the X-axis direction is set to be a Y-axis direction. The second electrode 20 is, for example, a drain electrode. The second electrode 20 is provided, for example, in the trench 70, and is in contact with the n′GaN layer 33. It is desirable that the second electrode 20 be in ohmic contact with the nitride semiconductor layer 30 in the same manner as the first electrode 10. As a material of the second electrode 20, for example, at least one of aluminum (Al), nickel (Ni), copper (Cu) and titanium (Ti) metal is used.

The third electrode 40 is provided spaced from the first electrode 10 in the second direction intersecting the Z-axis direction. The second direction is, for example, the X-axis direction. The third electrode 40 is, for example, a gate electrode. In this example, the third electrode 40 is provided between two first electrodes 10 in the X-axis direction. As a material of the third electrode 40, for example, at least one of aluminum (Al), nickel (Ni), copper (Cu) and titanium (Ti) metal is used.

The semiconductor device 100 further includes a gate insulation layer 50. The gate insulation layer 50 is provided between the third electrode 40 and the nitride semiconductor layer 30, i.e., it lines the trench in which the third electrode 40 is located. For example, an insulator such as silicon oxide (SiO₂ and the like) and the like are used for the gate insulation layer 50. For example, the n implantation layer 36, the pGaN layer 35 and the nGaN layer 34 are etched using an inductively coupled plasma reactive ion etching (ICP-RIE) method and the like to form the trench of a predetermined depth. The gate insulation layer 50 and the third electrode 40 are sequentially formed so as to be embedded in this trench.

Here, one direction intersecting the X-axis direction is set to be a third direction. The third direction is, for example, the Y-axis direction. The Y-axis direction perpendicularly intersects with each of the Z-axis direction and the X-axis direction.

In this example, the first electrode 10, the second electrode 20, and the third electrode 40 extend in the Y-axis direction. Both the first electrode 10 and the third electrode 40 are formed in a stripe shape extending parallel to each other along a front surface side of the nitride semiconductor layer 30. The second electrode 20 is formed in the trench 70 extending inwardly of the rear surface side of the nitride semiconductor layer 30, which extends parallel to the third electrode 40. Functionality of each electrode 10, 20 as a source and a drain electrode are interchangeable.

In the nitride semiconductor layer 30 described above, when an electric field is applied between the first electrode 10 and the second electrode 20 (between a source and a drain), an electron 39 moves from the first electrode 10 toward the second electrode 20. This electron 39 flows, for example, in the Z-axis direction parallel to a c-axis direction 80. In the nitride semi conductor layer crystal structure, the c-axis direction 80 is a direction perpendicular to a c surface (polar surface) of the crystal structure of the nitride semiconductor layer 30.

As illustrated in FIGS. 1B and 2, the first electrode 10 includes a first surface 11. The second electrode 20 includes a second surface 21. The second surface 21 is spaced from the first surface 11 in the Z-axis direction. The third electrode 40 includes a third surface 41. A portion of the nitride semiconductor layer 30 extends between the first surface 11 and the second surface 21, and between the third surface 41 and the second surface 21. The first surface 11 and the second surface 21 are in contact with the nitride semiconductor layer 30. The first surface 11 and the second surface 21 face each other across the portion of the intervening nitride semiconductor layer 30. The third surface 41 and the second surface 21 are in contact with the nitride semiconductor layer 30. The third surface 41 and the second surface 21 face each other across the portion of the intervening nitride semiconductor layer 30.

A plurality of at least one of convex portions and concave portions are provided on the second surface 21 of the second electrode 20. In this example, a plurality of convex portions 22 is provided on the second surface. That is, the second electrode 20 includes a plurality of convex portions 22. The nitride semiconductor layer 30 is provided between the first surface 11 and the second surface 21, and between the third surface 41 and the second surface 21. The plurality of convex portions 22 are provided between the second surface and the first surface 11. The plurality of convex portions 22 may be provided between the second surface and the third surface 41. In this example, the plurality of convex portions 22 on the second surface 21 of the second electrode 20 face the first surface 11 of the first electrode 10 and the third surface 41 of the third electrode 40.

The second surface 21 includes a first portion 21a located between the second surface and the first surface 11, and a second portion 21b located between the second surface and the third surface 41. The plurality of convex portions 22 may be provided in the first portion 21a of the second surface 21 facing the first surface 11, and in the second portion 21b facing the third surface 41, and thus the first and second portions 21a, 21b of second surface 21 may form the same base plane from which the convex portions project. Additionally, the convex surface portions and/or convex surface portions may be provided only in the first portion 21a, where the first and second electrodes 10, 20 face one another, and the second portion 21b may be a plane, i.e., flat. Accordingly, it is possible to reduce the number of process steps required for formation of convex portions. Moreover, a plurality of small convex portions may be provided in the second portion 21b. For example, a convex portion smaller than the convex portion 22 formed in the first portion 21a may be provided in the second portion 21b.

The plurality of convex portions 22 are formed at least in the first portion 21a facing the first surface 11 of the second surface 21. A cross-section of one of the plurality of convex portions 22 is, for example, arcuate. The plurality of convex portions 22 project convexly into the nitride semiconductor layer 30 (n⁺GaN layer 33). In addition, instead of the plurality of convex portions 22, a plurality of concave portions such that the nitride semiconductor layer 30 (n⁺GaN layer 33) extends thereinto may be provided. The plurality of concave portions are, for example, in a dimple (recess) shape. In addition, a plurality of both concave and convex portions may be provided. The plurality of both concave and convex portions include a plurality of convex portions and concave portions, respectively.

The plurality of convex portions 22 are formed by, for example, etching the n⁺GaN layer 33 at the base of the trench 70 into a predetermined shape before forming the second electrode 20 therein. As an etching method, for example, either dry etching or wet etching may be used. Here, one to 100 convex portions 22 are provided per unit area (for example, per 10 square micrometers (μm²)).

In this example, the plurality of convex portions 22 are formed having a cross-section arcuate in the X-axis direction and the Y-axis direction, i.e., the three dimensional structure extends in the x-y plane with the thickness changing in the z direction at different locations across the x-y plane. The plurality of convex portions 22 may be also formed to have a cross-section arcuate only in the X-axis direction, i.e., the z direction thickness changes only along the x direction. The plurality of convex portions 22 may be formed to have a cross-section arcuate only in the Y-axis direction, i.e., the z direction thickness changes only in the Y direction.

Here, the nitride semiconductor layer 30 includes a front surface 38. The front surface 38 is a surface on which the first electrode 10 is formed. It is desirable that an angle between the Z-axis direction and one of an m surface, an a surface, and a c surface of the crystal structure of the nitride semiconductor layer 30 be from 85 degrees to 90 degrees. The m surface, the a surface, and the c surface are crystal surfaces (planes) of the nitride semiconductor layer 30. The Z-axis direction corresponds to a direction 38a toward the second electrode 20 from the first electrode 10. That is, it is desirable the front surface 38 have an angle of from 0 degrees to 5 degrees with respect to any crystal surface as among one of the m surface, the a surface, and the c surface. In terms of flatness and the like of the front surface 38, the front surface 38 desirably has an angle from 0 degrees to 1 degree with respect to the crystal surface, and more desirably has an angle from 0 degrees to 0.3 degrees.

A crystal structure of the nitride semiconductor layer 30 may be a hexagonal crystal system. A surface (top surface of hexagonal prism) to which the c axis is perpendicular along an axis direction of a hexagonal prism is the c surface, that is, the (0001) surface. In the nitride semiconductor layer 30, a polarization direction is along the c axis. The c surface is a polar surface. On the other hand, a side surface of the hexagonal prism (prismatic surface) is the m surface which is equivalent to a (1-100) surface, that is, the {1-100} surface. A surface passing through a pair of edges or intersecting sides of the prism structure which are not adjacent to each other is the “a” surface which is equivalent to a (11-20) surface, that is, the {11-20} surface. The m surface and the a surface are non-polar surfaces.

FIG. 3 is a schematic cross-sectional view which illustrates another semiconductor device according to the first embodiment.

A semiconductor device 101 of this example includes the first electrode 10, the second electrode 20, and the nitride semiconductor layer 30.

FIG. 3 illustrates a cross-section corresponding to a cross-section taken along line B1-B2 of FIG. 1A.

As illustrated in FIG. 3, the second electrode 20 includes a plurality of convex portions 22. A cross-section of any one of the plurality of convex portions 22 is, for example, trapezoidal in cross section.

In this example, the plurality of convex portions 22 are provided to have a trapezoidal cross-section extending in both the X-axis direction and the Y-axis direction. The plurality of convex portions 22 may be trapezoidal in cross-section only in the X-axis direction. The plurality of convex portions 22 may be trapezoidal in cross-section only in the Y-axis direction. In this example, a plurality of concave portions which are concave with respect to the nitride semiconductor layer 30 may be also provided. In addition, both concave and convex portions may also be provided. The plurality of both concave and convex portions include a plurality of convex portions and concave portions, respectively.

FIG. 4 is a schematic cross-sectional view which illustrates still another semiconductor device according to the first embodiment.

A semiconductor device 102 of this example includes the first electrode 10, the second electrode 20, and the nitride semiconductor layer 30.

FIG. 4 illustrates a cross-section corresponding to a cross-section taken along line B1-B2 in FIG. 1A.

As illustrated in FIG. 4, the second electrode 20 includes a plurality of convex portions 22. A cross-section of any one of the plurality of convex portions 22 is, for example, in a triangular shape.

In this example, the plurality of convex portions 22 have a triangular cross-section extending in both the X-axis direction and the Y-axis direction. The plurality of convex portions 22 may be triangular in cross-section only in the X-axis direction. The plurality of convex portions 22 may be triangular in cross-section only in the Y-axis direction. In this example, a plurality of concave and convex portions which are concave with respect to the nitride semiconductor layer 30 may be provided. Moreover, a plurality of both concave and convex portions may also be provided. The plurality of both concave and convex portions include a plurality of convex portions and concave portions, respectively.

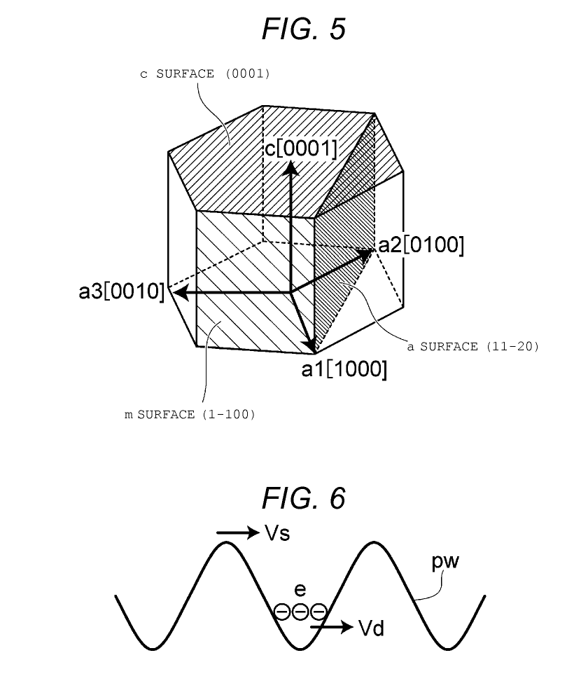

FIG. 5 is a schematic diagram which illustrates a crystal structure of a nitride semiconductor.

As illustrated in FIG. 5, the crystal structure of the nitride semiconductor may be a hexagonal crystal system. The surface of the crystal structure (prism) to the c-axis extending along an axial direction of a hexagonal prism is perpendicular (top surface of the hexagonal prism) is the c surface, that is, a (0001) surface. In the nitride semiconductor, a polarization direction is along the c-axis. The c surface is a polar surface.

On the other hand, a side surface (prismatic surface) of hexagonal prism is the m surface which is equivalent to a (1-100) surface, that is, the {1-100} surface. A surface passing through a pair of edges or corners which are not adjacent to each other is the “a” surface which is equivalent to a (11-20) surface, that is, the {11-20} surface. The m surface and the a surface are non-polar surfaces.

Hereinafter, a case in which the front surface 38 of the nitride semiconductor layer 30 is the c surface, which is a polar surface, will be described as an example. The c-axis direction 80 (refer to FIG. 1B) is a direction perpendicular to the c surface, that is, a direction parallel to the Z-axis direction. The following matter may be also applied to a case where the front surface 38 is the m surface or the a surface which are non-polar surfaces.

FIG. 6 is a diagram which illustrates characteristics of the nitride semiconductor.

In a so-called piezoelectric semiconductor such as a GaN, acoustic waves are locally generated in a part of the crystal to form a so-called acoustic domain. In case of a horizontal transistor, when a source electrode is parallel to a drain electrode parallel to the c surface, an acoustic domain is generated in any direction. In the m surface and the a surface, when a source electrode, a gate electrode, and a drain electrode are formed so as to form the electric field in parallel to the polarization direction (c-axis direction), the acoustic domain is generated.

Since the drift speed of electrons is generally faster than the speed of sound in the nitride semiconductor, a resonance phenomenon due to acoustic amplification between the source electrode and the drain electrode in which the electric field is formed occurs in some cases. When the resonance phenomenon occurs, electrons are trapped in a bottom (trough) of the piezoelectric potential wave, and current saturation occurs.

Current saturation occurs at a place at which the acoustic amplification occurs, and resistance to electron flow in this region is apparently increased. Accordingly, in a state where a voltage is applied to a crystal, the electric field is concentrated on this region to generate a high electric field domain. That is, an electric field concentration occurs along with a resonance phenomenon, and when this state continues, there is a concern that a breakdown of the crystal itself may occur due to an insulation breakdown and the like.

It is considered that the resonance phenomenon due to the acoustic amplification occurs because thermal noise acoustic waves in the crystal are locally amplified in the semiconductor device due to reflection resonance. The resonance phenomenon will be described, for example, as follows.

As illustrated in FIG. 6, when transporting the acoustic waves in the piezoelectric semiconductor, waves make potential waves pw at a bottom of the conduction band due to the piezoelectricity. Electrons e are captured in this potential valley (trough). The electric field E is applied in the same direction as a transportation direction of acoustic waves to accelerate the electrons e. When the drift speed of the electrons e (Vd in the figure) exceeds a transportation speed (speed of sound: Vs in the figure) of the potential wave pw, an energy of the electrons e flows in a wave system, and acoustic waves are amplified, and thereby a potential valley becomes deeper.

When comparing piezoelectric constants of GaN planes with each other, there is a relationship of |e33|>|e15|. Here, e33 is, for example, 0.73, and e15 is, for example, 0.33. Accordingly, when an electric field of the same magnitude is applied, a greater stress is generated when the electric field is applied in a direction parallel to a spontaneous polarization than when the electric field is applied in a direction perpendicular to the spontaneous polarization. Moreover, expansion and contraction distortion occurs with a large volume change of the GaN crystal when the electric field is applied in a direction parallel to the spontaneous polarization. On the other hand, a slip-distortion occurs with a relatively small volume change when the electric field is applied in a direction perpendicular to the spontaneous polarization. Deformation of a potential is proportional to the volume change. Therefore, a larger potential change in an amplitude occurs when the electric field is applied in a direction parallel to the spontaneous polarization direction.

On the other hand, a source electrode and a drain electrode are formed spaced from each other in the Z-axis direction in the vertical transistor. Even in a vertical transistor, when a crystal surface of one of the m surface, the a surface, and the c surface is a front surface in the vertical transistor, and the source electrode and the drain electrode are parallel to each other, a potential change may occur in any direction.

When the c surface is a front surface in the vertical transistor, a direction in which the electric field is applied between the source electrode and the drain electrode is parallel to a direction (c-axis direction) of the spontaneous polarization. On the other hand, when the m surface or the a surface is a front surface, a direction in which electric field is applied between the source electrode and the drain electrode is perpendicular to a direction of the spontaneous polarization. Therefore, it may be said that the c surface has a larger potential change than the m surface or the a surface. However, since the potential change is generated in any case, resonance phenomenon due to acoustic amplification may occur in each case. However, when the m surface or the a surface is a front surface, an electric field is applied in a direction perpendicular to a polarization direction (c-axis direction). Therefore, it is considered that acoustic amplification is less than when the c surface is a front surface.

When a depth of a wave valley (trough) is less than the thermal energy of the electrons e, the electrons e may freely emit out from this valley. Thus, the electrical conductivity is not affected, but ohmic properties are maintained. However, when the acoustic waves are amplified, and the depth of the valley is sufficiently greater than the thermal energy of the electrons, the electrons e may no longer emit out from the valley, and will instead move at the speed of sound with acoustic waves.

A current saturation occurs as described above. Then, if there is some unevenness in the crystal of the semiconductor device and acoustic amplification is thus more likely to occur in a certain region than other regions, current saturation occurs only in this region to apparently increase electrical resistance of this region. Accordingly, in a state where a constant voltage is applied to a crystal of the semiconductor device, the electric field is concentrated on this region to complete a high electric field domain. That is, an electric field concentration occurs along with the resonance phenomenon, and when this state continues, there is a concern that a breakdown of the crystal itself may occur due to an insulation breakdown and the like.

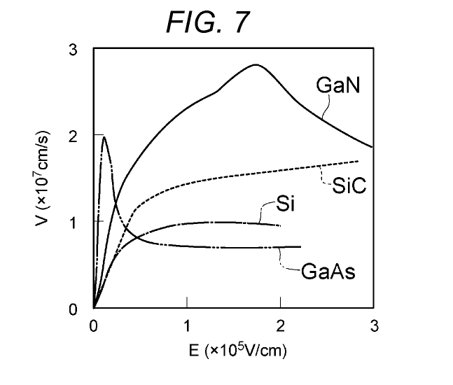

FIG. 7 is a graph which illustrates a relationship between an electric field and a drift speed of electrons in each semiconductor.

A vertical axis of FIG. 7 represents a drift speed V (×10⁷ cm/s) of electrons. A horizontal axis represents an electric field E (×10⁵ V/cm).

As illustrated in FIG. 7, when the electric field E is 0.2×10⁵ V/cm or more, the drift speed V of electrons in the GaN is faster than that of electrons in SiC, Si or GaAs.

When a distance between a source electrode and a drain electrode is about 20 micrometers (μm), the electric field becomes about 100 kV/cm. As illustrated in FIG. 7, a drift speed V of electrons in the GaN at the 100 kV/cm electric field is about 2×10⁷ cm/s. A speed of sound in the GaN crystal is 6.6×10⁵ cm/s, and thus the drift speed V of electrons is greater than the speed of sound. Therefore, a resonance phenomenon causing electron trapping due to amplification of the acoustic waves may occur in the nitride semiconductor.

As described above, when the c surface which is a polar surface is particularly used in the nitride semiconductor, it is desirable to consider piezoelectric characteristics as a piezoelectric semiconductor. In a structure without considering the piezoelectric characteristics, it is difficult to take advantage of excellent characteristics of the nitride semiconductor.

According to the embodiment, the interval (distance) between electrodes (between a source electrode and a drain electrode) may be uneven by providing a plurality of convex portions (or a plurality of concave portions or a plurality of concave and convex portions) as the surface 21 of the drain electrode 20 in the vertical transistor. For example, the facing surfaces of the source electrode and the drain electrode are in a non-parallel state. Accordingly, acoustic waves generated between the electrodes may be prevented from being reflected back in the same direction, in other words, the convex and/or concave surfaces scatter the reflected waves so they cannot amplify due to reflected reinforcement of the waves. Therefore, acoustic amplification is unlikely to occur, and a resonance phenomenon due to the acoustic amplification hardly occurs. Accordingly, insulation breakdown and the like may be prevented, thereby improving reliability. That is, it is possible to provide a semiconductor device which may have improved reliability.

A shape, the number, disposition, and the like of the plurality of convex portions 22 are not limited. The plurality of convex portions 22 may not be necessarily disposed in a regular manner. For example, the second surface 21 of the second electrode 20 may be formed into an uneven surface using a method such as etching, and the plurality of convex portions 22 may be formed in irregular directions.

### Second Embodiment

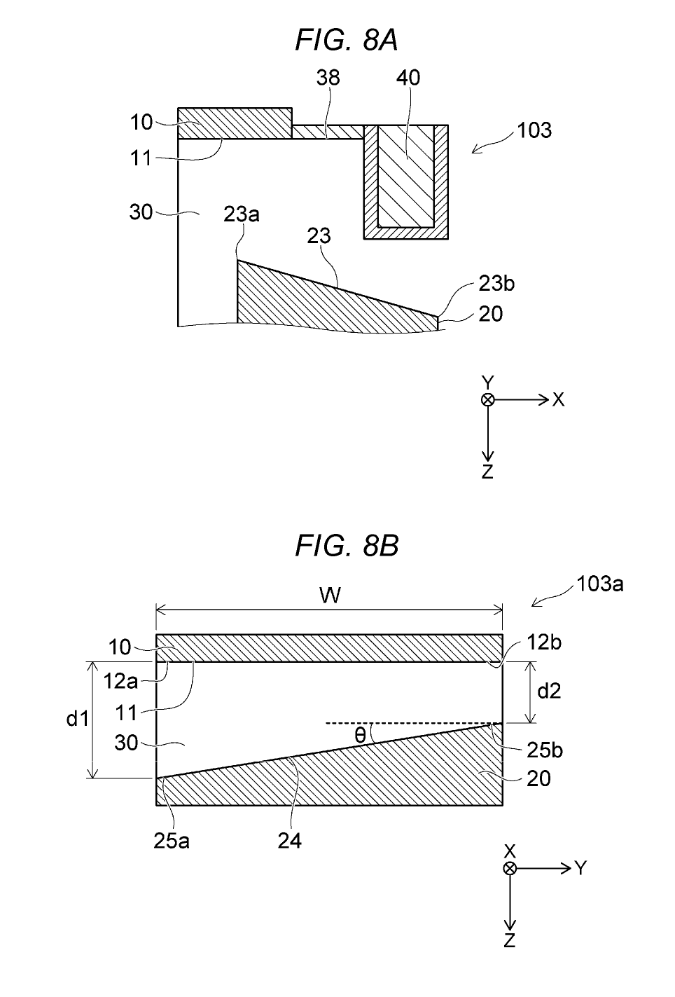

FIGS. 8A and 8B are schematic cross-sectional view which illustrates a main part of a semiconductor device according to a second embodiment.

As illustrated in FIG. 8A, a semiconductor device 103 includes a first electrode 10, a second electrode 20, and a nitride semiconductor layer 30.

FIG. 8A illustrates a cross-section corresponding to the cross-section taken along line A1-A2 of FIG. 1A.

The first electrode 10 includes a first surface 11 facing the second electrode 20. The second electrode 20 includes a second surface 23 facing the first surface 11. The second surface 23 is inclined with respect to the first surface 11. The second surface 23 is inclined with respect to the first surface 11, for example, in the X-axis direction. The second surface 23 includes a first upper end 23a at the first electrode 10 side and a second upper end 23b at the third electrode 40 side. In this example, the second surface 23 is inclined so that the position of the first upper end 23a is higher than that of the second upper end 23b. On the contrary, the second surface 23 may also be inclined so that the position of the first upper end 23a is lower than that of the second upper end 23b.

An inclination of the second surface 23 does not need to be continuous. The second surface 23 may be obtained by combining a plane which is parallel to the first surface 11 and an inclined surface which is inclined with respect to the first surface 11. Moreover, a cross-section of the second surface 23 may be formed in a stepwise shape.

As illustrated in FIG. 8B, a semiconductor device 103a includes the first electrode 10, the second electrode 20, and the nitride semiconductor layer 30.

FIG. 8B illustrates a cross-section corresponding to the cross-section taken along line B1-B2 of FIG. 1A.

The first electrode 10 includes the first surface 11 facing the second electrode 20. The second electrode 20 includes the second surface 24 facing the first surface 11. The second surface 24 is inclined with respect to the first surface 11. The first surface 11 includes the first end 12a and the second end 12b. The second end 12b is apart from the first end 12a in the Y-axis direction. The second surface 24 includes a third end 25a and a fourth end 25b. The third end 25a is aligned with the first end 12a in the Z-axis direction. The fourth end 25b is spaced from the third end 25a in the Y-axis direction. A first distance d1 between the first end 12a and the third end 25a is longer than a second distance d2 between the second end 12b and the fourth end 25b. On the contrary to this, the first distance d1 may also be shorter than the second distance d2.

Here, by a distance (electrode length) W (micrometers: μm) between the first end 12a and the second end 12b, the first distance d1 (micrometers: μm), the second distance d2 (micrometers: μm), an inclination angle θ (degree: deg) between the second surface 24 and the first surface 11 is represented by a first formula described below.

θ=tan⁻¹{(d1−d2)/W} (1)

In the embodiment, θ is, for example, from 0.1 to 88.1.

When the inclination angle θ is in the above range, a resonance may be effectively suppressed.

As described above, according to the embodiment, by inclining a drain electrode with respect to a source electrode in the vertical transistor, an interval between electrodes (between the source electrode and the drain electrode) is uneven. Accordingly, acoustic waves generated between the electrodes may be prevented from being reflected back in the same direction. Therefore, acoustic amplification is unlikely to occur, and a resonance phenomenon due to the acoustic amplification hardly occurs. Accordingly, insulation breakdown and the like may be prevented, thereby improving reliability.

### Third Embodiment

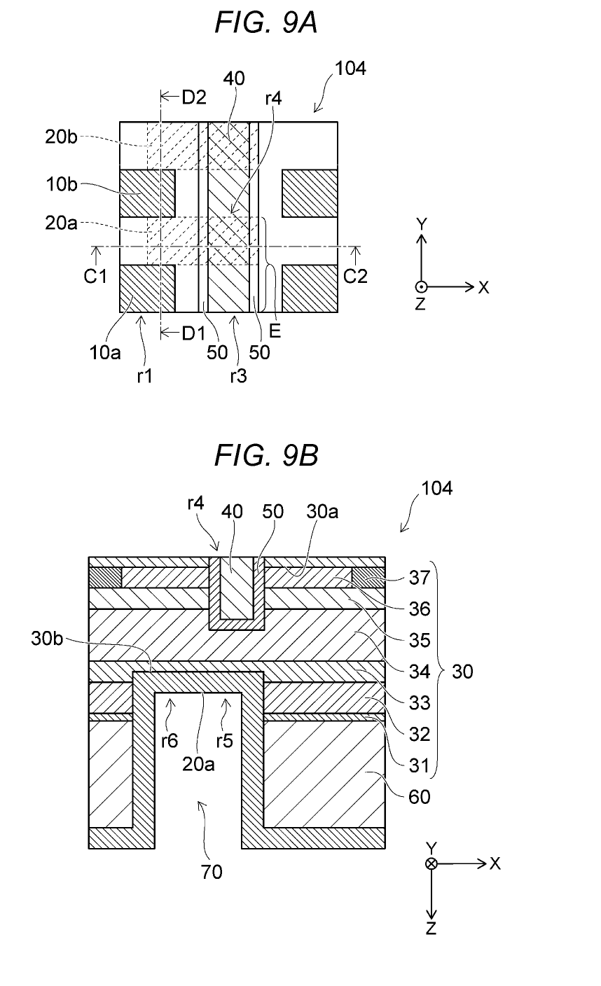

FIGS. 9A and 9B are schematic diagrams which illustrate a semiconductor device according to a third embodiment.

FIG. 9A is a schematic plan view which illustrates the semiconductor device according to the third embodiment.

FIG. 9B is a schematic cross-sectional view taken along line C1-C2 of FIG. 9A.

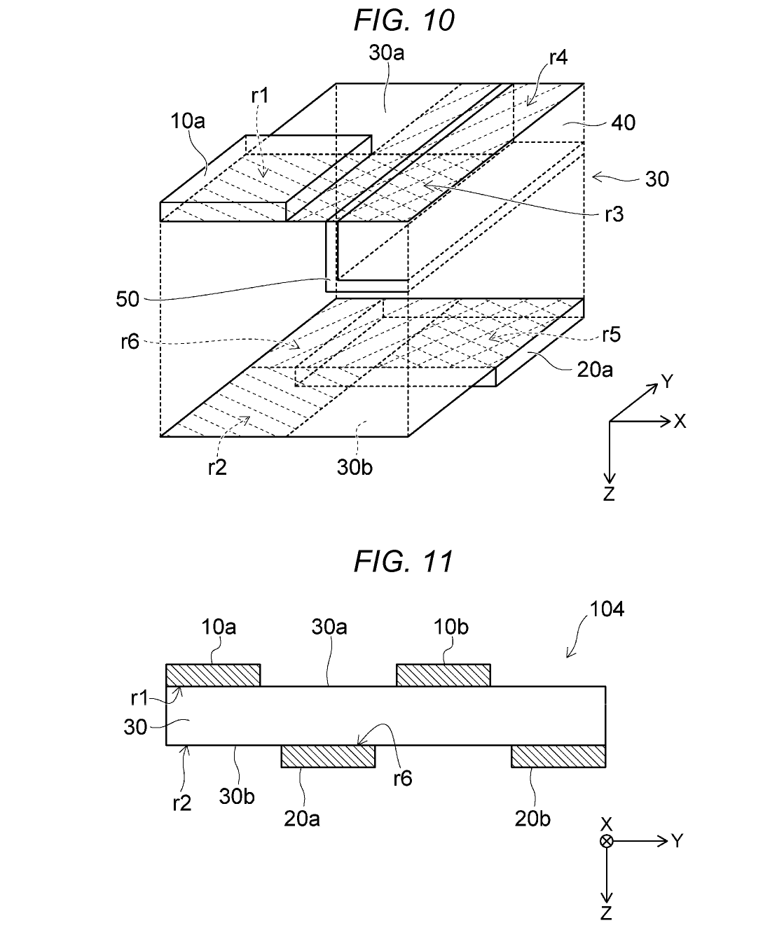

FIG. 10 is a schematic perspective view which illustrates a part (E portion) of FIG. 9A.

FIG. 11 is a schematic cross-sectional view taken along line D1-D2 of FIG. 9A.

As illustrated in FIGS. 9A and 9B, a semiconductor device 104 according to the embodiment includes first electrodes 10a and 10b, second electrodes 20a and 20b, nitride semiconductor layer 30, and a third electrode 40. The first electrodes 10a and 10b are source electrodes. The second electrodes 20a and 20b are drain electrodes. The third electrode 40 is a gate electrode.

The nitride semiconductor layer 30 includes a first surface 30a and a second surface 30b. The second surface 30b is spaced from the first surface 30a in a Z-axis direction. The second surface 30b is a surface on an opposite side to the first surface 30a. The first electrodes 10a and 10b are provided on the first surface 30a. The third electrode 40 is provided on the first surface 30a. The second electrodes 20a and 20b are provided on the second surface 30b. The second electrodes 20a and 20b do not overlap with the first electrodes 10a and 10b in a direction joining the first surface 30a and the second surface 30b, i.e., a planar projection of one of the electrodes 20a, 20b in a direction across the nitride semiconductor layer does not overlay with the position of the other of the electrodes 20a, 20b. Here, “not overlapping” between the second electrodes 20 and 20b and the first electrodes 10a and 10b includes an overlap of only a part between the electrodes. For example, an overlap within 10% of an electrode width may be allowed.

For example, as illustrated in FIG. 10, the nitride semiconductor layer 30 includes a first region r1, a second region r2, a third region r3, a fourth region r4, a fifth region r5, and a sixth region r6. The second region r2 is spaced from the first region r1 in the Z-axis direction. The third region r3 is aligned with the first region r1 in the X-axis direction. The fourth region r4 is aligned with the third region r3 in the Y-axis direction. The fifth region r5 is spaced from the fourth region r4 in the Z-axis direction. The sixth region r6 is aligned with the fifth region r5 in the X-axis direction and the second region r2 in the Y-axis direction. That is, the first region r1, the third region r3, and the fourth region r4 are provided on the first surface 30a. The second region r2, the fifth region r5, and the sixth region r6 are provided on the second surface 30b.

In this example, the first electrode 10a is provided in the first region r1. The second electrode 20a is provided in the fifth region r5 and the sixth region r6. The third electrode 40 is provided in the third region r3 and the fourth region r4. However, as long as the second electrode 20a is not provided in the second region r2 facing the first region r1, the embodiment is not limited to this example.

As illustrated in FIG. 11, the first electrodes 10a and 10b and the second electrodes 20a and 20b are alternately (in a zigzag shape) aligned with each other along the Y-axis direction. That is, the first electrodes 10a and 10b and the second electrodes 20a and 20b are disposed to not overlap with each other (not to overlapingly face each other) in the Z-axis direction. The number of the first electrodes 10 and the second electrodes 20 is not limited to the example.

As described above, according to the embodiment, a source electrode and a drain electrode are disposed not to overlap (or not substantially overlap, such as by 10% or less) with each other in the vertical transistor, and thereby acoustic waves generated between the electrodes may be prevented from being reflected back in the same direction. Therefore, acoustic amplification is unlikely to occur, and a resonance phenomenon due to the acoustic amplification hardly occurs. Accordingly, insulation breakdown and the like may be prevented, thereby improving reliability.

### Fourth Embodiment

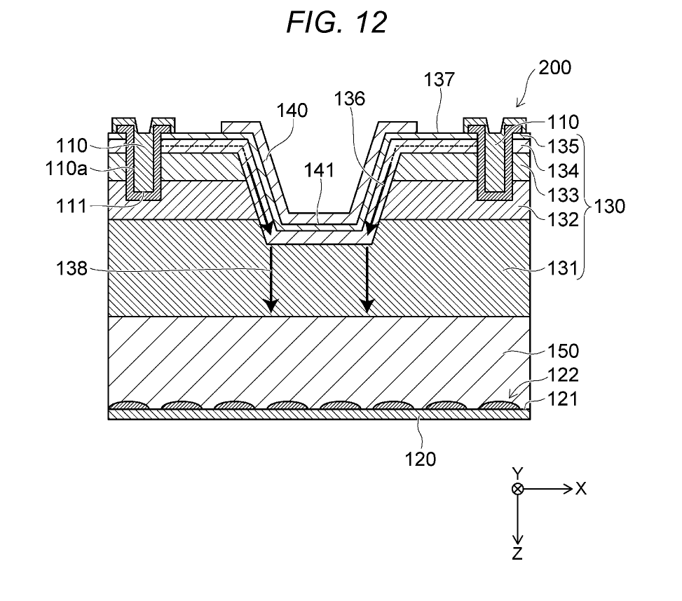

FIG. 12 is a schematic cross-sectional view which illustrates a semiconductor device according to a fourth embodiment.

A semiconductor device 200 of the embodiment is a hetrojunction electron mobility transistor (HEMT) which uses a nitride semiconductor.

The semiconductor device 200 includes a first electrode 110, a second electrode 120, a nitride semiconductor layer 130, a third electrode 140, and a substrate 150. The first electrode 110 is, for example, a source electrode. The second electrode 120 is, for example, a drain electrode. The third electrode 140 is, for example, a gate electrode. For example, GaN is used for the substrate 150. GaN is used for the nitride semiconductor layer 130. The nitride semiconductor layer 130 includes an n⁻GaN layer 131, a p⁺GaN layer 132, a n⁺GaN layer 133, a re-growth GaN layer 134, and a re-growth AlGaN layer 135. A two-dimensional electron gas (2 DEG) 136 is formed in a vicinity of an interface between the re-growth GaN layer 134 and the re-growth AlGaN layer 135. A front surface 137 of the nitride semiconductor layer 130 is, for example, the c surface.

That is, the nitride semiconductor layer 130 includes the re-growth GaN layer 134 and the re-growth AlGaN layer 135. The re-growth AlGaN layer 135 is provided between the re-growth GaN layer 134 and the first electrode 110, and between the re-growth GaN layer 134 and the third electrode 140.

In the nitride semiconductor layer 130 described above, when an electric field is applied between the first electrode 110 and the second electrode 120 (between a source electrode and a drain electrode), electrons 138 flow toward the second electrode 120 from the first electrode 110. The electrons 138 flow in a Z-axis direction parallel with the c-axis direction.

An example of a method of manufacturing the semiconductor device 200 will be described.

For example, a GaN substrate which sets the c surface as a front surface is prepared. The GaN substrate is an example of the substrate 150. The substrate 150 is prepared by producing a bulk GaN ingot using a liquid phase growth such as a sodium flux method, and a melt growth method such as an ammonothermal method, and a cutting the ingot so that the c surface becomes a front surface.

On the c surface of the substrate 150, for example, using a MOVPE method, the n⁻GaN layer 131, the p⁺GaN layer 132, and the n⁺GaN layer 133 are sequentially formed by epitaxial growth, respectively.

The p⁺GaN layer 132 and the n⁺GaN layer 133 are etched into an inclined shape using, for example, an ICP-RIE method, and AlGaN/GaN is re-grown by, for example, the MOVPE method. Accordingly, the re-growth GaN layer 134 and the re-growth AlGaN layer 135 are formed. A 2 DEG layer 136 is formed on a slope between the re-growth GaN layer 134 and the re-growth AlGaN layer 135.

In addition to GaN, substrates of gallium oxide, SiC, Si, sapphire, and the like may be used for the substrate 150. When epitaxial growing the nitride semiconductor layer 130 whose front surface is the c surface on the substrate 150 using a SiC substrate or a sapphire substrate, it is desirable that a surface orientation of a front surface of a SiC substrate or the sapphire substrate be the c surface. However, the front surface does not necessarily have to be the c surface depending on a growth condition.

After the nitride semiconductor layer 130 is formed on the substrate 150 as described above, the first electrode 110, the second electrode 120, and the third electrode 140 are formed. These electrodes are formed using, for example, an electron-beam deposition and a lift-off method.

Specifically, the re-growth AlGaN layer 135, the re-growth GaN layer 134 and the n⁺GaN layer 133 are etched to expose the p⁺GaN layer 132. For a potential fixation of the p⁺GaN layer 132, a p-type ohmic electrode 110a of a recess structure is formed on the exposed p⁺GaN layer 132. The first electrode 110 is formed on an upper portion of this p-type ohmic electrode 110a. Accordingly, a short circuit and grounding is performed. Then, the second electrode 120 is formed across an entire surface of a rear surface of the substrate 150, and an alloying annealing process is performed.

Here, the first electrode 110 includes the first surface 111. The first surface 111 faces the second electrode 120. The second electrode 120 includes the second surface 121. The second surface 121 faces the first surface 111. That is, the substrate 150 and the nitride semiconductor layer 130 are disposed between the first surface 111 and the second surface 121. For example, a plurality of convex portions 122 is provided on the second surface 121. A cross-section of one of the plurality of convex portions 122 is, for example, in an arc shape. The plurality of convex portions 122 are formed by etching a rear surface of the substrate 150 into a predetermined shape. For etching, for example, one of a dry etching method and a wet etching method may be used.

Finally, the third electrode 140 is formed between two first electrodes 110. The third electrode 140 is formed on the re-growth AlGaN layer 135. Prior to the formation of the third electrode 140, a dielectric layer may be formed, when necessary as agate insulation film, on a front surface on which the first electrode 110 is formed. The dielectric may be a material such as SiO₂, SiN, and AIN with which desired gate electrode characteristics are obtained. The dielectric is formed by, for example, a plasma enhanced chemical vapor deposition method (PECVD method), a low pressure chemical vapor deposition method (LPCVD method), an electron cyclotron resonance (ECR) sputtering method, and the like.

The semiconductor device 200 of the structure illustrated in FIG. 12 may be manufactured by the above manufacturing method.

In this manner, even when applying the structure of the embodiment to a vertical HEMT, a spacing interval between electrodes (between a source electrode and a drain electrode) may be uneven by providing a plurality of convex portions (or a plurality of concave portions or a plurality of concave and convex portions) in a drain electrode. For example, the interval between the electrodes is in a non-parallel state. Accordingly, acoustic waves generated between the electrodes may be prevented from being reflected back in the same direction. Therefore, acoustic amplification is unlikely to occur, and a resonance phenomenon due to the acoustic amplification hardly occurs. Accordingly, insulation breakdown and the like may be prevented, thereby improving reliability.

In the above embodiments, a case where the c surface is a front surface is illustrated and described. The embodiment may be applied to when an m surface or the a surface is set to be a front surface in the same manner as when the c surface is set to be a front surface.

In addition, the first and the fourth embodiments have a structure in which a convex portion is provided in a drain electrode and a spacing interval between the source and the drain electrodes is non-parallel. When providing an interposition layer which is interposed between the drain electrode and the nitride semiconductor layer, a convex portion may be provided not in the drain electrode, but on a surface of the interposition layer at the nitride semiconductor layer side. Semiconductor substrate materials such as Si, SiC, and sapphire are used for the interposition layer. This also applies to when providing an inclined drain electrode.

In the disclosure, a nitride semiconductor includes semiconductors of all compositions in which composition ratios x, y, and z are changed within respective ranges in a chemical formula which is BₓIn_{y}Al_{z}Ga_{1-x-y-z}N (0≦x≦1, 0≦y≦1, 0≦z≦1, x+y+z≦1). Furthermore, in the chemical formula, those which further include group V elements other than N (nitrogen), those which further include various elements added to control various physical properties such as a conductivity type, and those which further include various elements unintentionally contained are regarded to be included in the nitride semiconductor.

According to the embodiment, it is possible to provide a semiconductor device which may improve reliability.

The exemplary embodiments are described with reference to specific examples. However, the exemplary embodiments are not limited to these specific examples. For example, with regard to a specific configuration of each element such as the first electrode, the second electrode, the third electrode, and the nitride semiconductor layer, as long as the exemplary embodiment is performed in the same manner by being appropriately selected from a range known by those skilled in the art, and the same effect may be obtained, the specific configuration is included in a range of the exemplary embodiment.

Moreover, a configuration in which any two or more elements in each specific example are combined in a technically feasible range is included in the range of the exemplary embodiment as long as a spirit of the exemplary embodiment is included.

In addition, based on the semiconductor device described above as in the exemplary embodiments, all semiconductor devices which may be obtained by appropriately changing a design by those skilled in the art is also within a scope of the exemplary embodiments as long as including a spirit of the exemplary embodiment.

It should be understood by those skilled in the art that various changes and modifications may be conceived and these correction examples and modification examples fall within the scope of the exemplary embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode having a first surface;
a second electrode having a second surface spaced from the first surface in a first direction, the second surface having at least a portion thereof non-parallel to the first surface;
a third electrode spaced from the first electrode in a second direction intersecting the first direction; and
a nitride semiconductor layer that is provided between the first surface and the second surface, and between the third electrode and the second surface.

2. The device according to claim 1, wherein the non-parallel surface of the second surface comprises a plurality of convex surface portions and a plurality of concave surface portions between the convex portions.

3. The device according to claim 2,
wherein a cross-section of one of the convex surface portions and the concave surface portions has an arcuate shape.

4. The device according to claim 2,
wherein a cross-section of one of the convex surface portions and the concave surface portions has a trapezoidal shape.

5. The device according to claim 2,
wherein a cross-section of one of the convex surface portions and the concave surface portions has a triangular shape.

6. The device according to claim 1,
wherein the second surface includes a first portion disposed between the second surface and the first surface, and a second portion disposed between the second surface and the third electrode,
wherein the first portion comprises a plurality of convex surface portions and a plurality of concave surface portions between the convex portions, and
wherein the second portion is a plane.

7. The semiconductor device according to claim 1, wherein at least a portion of the second surface extends as a non-parallel plane to the first surface.

8. The semiconductor device according to claim 7, wherein the portion of the second surface facing the first surface extends as a non-parallel plane to the first surface, and the portion of the second surface facing the third electrode extends parallel to a surface of the third electrode facing the second electrode.

9. The device according to claim 1,
wherein the nitride semiconductor layer has a hexagonal crystal structure including an m surface, an a surface, and a c surface, and
wherein an angle between the first direction and one of the m surface, the a surface, and the c surface is from 85 degrees to 90 degrees.

10. The device according to claim 1,
wherein the first electrode is a source electrode, the second electrode is a drain electrode, and the third electrode is a gate electrode.

11. The device according to claim 1,
wherein the nitride semiconductor layer includes a GaN layer, and an AlGaN layer that is provided between the GaN layer and the first electrode, and between the GaN layer and the third electrode.

12. The device according to claim 1,
wherein the first electrode and the nitride semiconductor layer are in ohmic contact with each other, and
wherein the second electrode and the nitride semiconductor layer are in ohmic contact with each other.

13. A semiconductor device comprising:
a first electrode having a first surface;
a second electrode having a second surface inclined with respect to the first surface and spaced from the first electrode in a first direction;
a third electrode spaced from the first electrode in a second direction intersecting the first direction; and
a nitride semiconductor layer located between the first surface and the second surface, and between the third electrode and the second surface.

14. The device according to claim 13,
wherein the first surface includes:
a first end, and
a second end that is spaced from the first end in a third direction intersecting the first direction and the second direction,
wherein the second surface includes:
a third end that is aligned with the first end in the first direction, and
a fourth end that is spaced from the third end in the third direction, and
wherein a first distance between the first end and the third end is greater than a second distance between the second end and the fourth end.

15. The device according to claim 14,
wherein, when a distance between the first end and the second end is W (micrometers), the first distance d1 (micrometers), and the second distance d2 (micrometers), tan⁻¹{(d1−d2)/W} is from 0.1 to 88.1.

16. The device according to claim 13,
wherein the nitride semiconductor layer has a hexagonal crystal structure including an m surface, an a surface, and a c surface, and
wherein an angle between the first direction and one of them surface, the a surface, and the c surface is from 85 degrees to 90 degrees.

17. The device according to claim 13,
wherein the first electrode is a source electrode, the second electrode is a drain electrode, and the third electrode is a gate electrode.

18. The device according to claim 13,
wherein the nitride semiconductor layer includes:
a GaN layer, and
an AlGaN layer that is provided between the GaN layer and the first electrode, and between the GaN layer and the third electrode.

19. The device according to claim 18,
wherein the first electrode and the nitride semiconductor layer are in ohmic contact with each other, and
wherein the second electrode and the nitride semiconductor layer are in ohmic contact with each other.

20. A semiconductor device comprising:
a nitride semiconductor layer having a first surface and a second surface on an opposite side of the nitride semiconductor layer from the first surface;
a source electrode located on the first surface;
a gate electrode located on the first surface; and
a drain electrode located on the second surface positioned such that a planar projection of the drain electrode across the nitride semiconductor does not overlap with the position of the source by more than 10 percent of the surface area of the source electrode.
